(19) United States
(12) Patent Application Publication
(10) Pub. No.: US 2014/0191780 A1
(43) Pub. Date: Jul. 10, 2014

(54) APPARATUS FOR TESTING A POWER SOURCE

(71) Applicant: EXPERIUM TECHNOLOGIES, LLC, Owings, MD (US)

(72) Inventor: Lance Palatini, Morris Plains, NJ (US)

(73) Assignee: EXPERIUM TECHNOLOGIES, LLC, Owings, MD (US)

(21) Appl. No.: 13/737,384

(22) Filed: Jan. 9, 2013

(51) Int. Cl. G01R 31/40

(52) U.S. Cl. CPC G01R 31/40
USPC 324/764.01

(57) ABSTRACT

A load device for applying an active load to a power source such as a wind turbine is characterized by an inductance and a resistive element both connected in parallel with the source. A relay is connected in series with the inductance and the resistive element and a controller is connected with the relays to selectively connect the inductance or resistive element with the source. By connecting a selected load with the power source, the source can be tested to evaluate that it is operating and performing properly.

### BACKGROUND OF THE INVENTION

The testing and commissioning of wind turbines present unique challenges due to the manner in which the turbine power is generated and distributed. As turbines are brought online in a power grid, there are significant spikes in voltage and frequency variance. Conventional programmable logic computer (PLC) driven load banks are unable to meet the testing demands due to these variances. In addition, the voltage spikes and frequency variations causes the testing procedure to fail. This results in delays and financial losses due to the inability to fully establish that the turbine is operating to manufacturer specification and performance metrics, which is a requirement for a wind turbine to become operational.

### BRIEF DESCRIPTION OF THE PRIOR ART

Load devices for turbine generators are known in the prior art as evidenced by the Gregg US patent application publication No. 2010/0329652 which discloses a turbine generator with an electrical circuit which provides reactive and resistive loads to the stator windings. The values of the reactance and resistance are selected so that the generator produces an output whose voltage and frequency varies with wind speed while the power output remains near a peak power output of the generator.

While the prior load devices operate satisfactorily for maintaining a constant power output, they are not suitable for testing the power output of a wind turbine to insure that the turbine is meeting its performance specifications. In addition, there is no capability of altering the resistance or inductance of the load device under computer control in accordance with the voltage across the inductance or reactance. Furthermore, there is no protection of the computer from voltage spikes and frequency variations in the output from the turbine.

The present invention was developed in order to overcome these and other drawbacks of the prior load devices by providing a resistive reactive load device which creates an electrical load on a power source such as a wind turbine by switching resistive or inductive elements across the terminals of the power source.

### SUMMARY OF THE INVENTION

Accordingly, it is a primary object of the invention to provide a load device for applying an active load to a power source such as a wind turbine. The device includes an inductor connected in parallel with the power source, a resistor connected in parallel with the power source and the inductor, and first and second relays connected in series with the inductor and resistor, respectively. A control device is connected with the relays to control the operation of the relays to deliver power from the power source to a selected inductor or resistor. This creates a desired load across the power source suitable for testing or evaluating the source without being susceptible to voltage spikes and frequency variations from the power source. If desired, multiple inductors and resistors, each with a series connected relay, are provided in the load device to provide a variety of loads for the power source.

A computer is preferably connected with the control device to select the inductive or resistive load to be applied to the power source in accordance with a testing procedure. In addition, a manual bypass device may be connected with each relay to over-ride the control vice and manually select the inductive or resistive load applied to the power source.

In an alternate embodiment, a load bank is provided which includes a plurality of the load devices as described above. The load bank includes a plurality of outputs which are connected at one end with each load device of the load bank and at the other end with a load step terminal of a power grid formed of a plurality of power sources such as wind turbines. The load bank provides a desired load across selected portions of the power grid for testing. A computer is connected with the load bank. It selectively operates the control devices of the load devices of the load bank to select the inductive or resistive load to be applied across the load step terminals of the power grid in accordance with the testing procedure.

### BRIEF DESCRIPTION OF THE FIGURES

Other objects and advantages of the invention will become apparent from a study of the following specification when viewed in the light of the accompanying drawing, in which:

FIG. 1 is a circuit diagram of a load device for testing a power source according to the invention; and

FIG. 2 is a block diagram of a load bank including a plurality of load devices for testing a power grid according to the invention.

### DETAILED DESCRIPTION

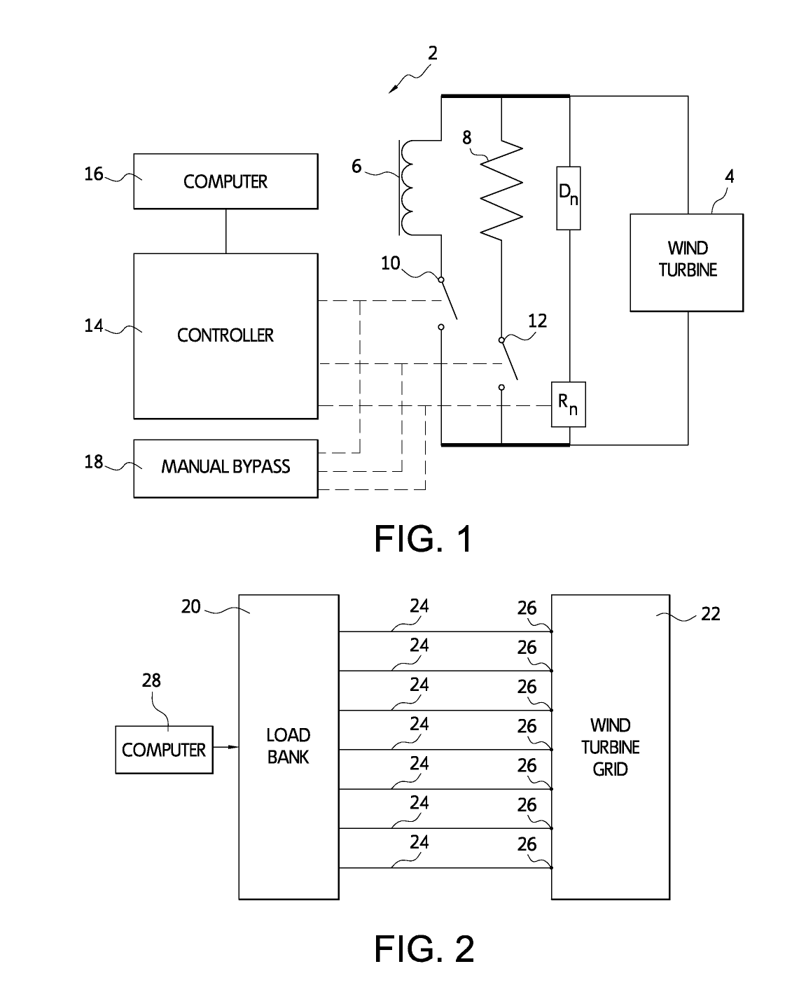

As shown in FIG. 1, a load device 2 according to a preferred embodiment is connected with the terminals of a power source such as a wind turbine 4. The load device is operable to apply an active load across the source in order to evaluate the output of the source.

More particularly, the load device includes an inductor 6 connected in parallel with the wind turbine and a resistive element 8 which is connected in parallel with the inductor and with the wind turbine. A first relay 10 is connected in series with the inductor and a second relay 12 is connected in series with the resistive element. The relays are operable to connect either the inductor or resistive element across the terminals of the wind turbine to provide the load. Operation of the first and second relays is controlled by a controller 14.

In an alternate embodiment, the load device includes a plurality of inductors and a plurality of resistive elements represented in FIG. 1 as Dₙ, each having a relay Rₙ connected in series. Where a plurality of inductors and resistive elements are provided, they each have different values, thereby increasing the spectrum of loads that can be applied to the power source.

Referring once again to FIG. 1, a computer 16 is connected with the controller 14 to control the operation of the relays in a desired sequence in accordance with a testing procedure. Thus, different loads are applied to the wind turbine in a selected order to sufficiently test the source under various conditions.

A manual bypass 18 such as a selector switch can be provided to override the controller. The bypass is connected with each relay and is used to manually select an inductor or resistive element to be applied across the power source during the testing procedure.

Referring now to FIG. 2, there is shown a load bank 20 connected with a wind turbine grid 22. The grid includes a plurality of turbines and the load bank is used to test each turbine of the grid. The load bank is formed of a plurality of load devices as shown in FIG. 1. Thus, each load device includes an inductor and a resistor connected in parallel and a relay connected in series with each inductor and resistor. Each load device further includes a control device connected with the relays to control the operation of each relay to select an inductor or resistor as the load for each power source. The load bank includes an output 24 for each load device within the bank. Each output is connected with a load step terminal 26 of the power grid in order to generate a desired load across a selected portion of the power grid. A computer 28 is connected with the control devices of the load devices within the load bank. The computer controls the operation of the control devices to select the inductive or resistive load to be applied across the load step terminals of the power grid in accordance with a testing procedure.

While the preferred forms and embodiments of the invention have been illustrated and described, it will be apparent to those of ordinary skill in the art that various changes and modifications may be made without deviating from the inventive concepts set forth above.

1. A load device for applying an active load on a wind turbine to evaluate the output of the wind turbine, comprising
(a) an inductor connected in parallel with the wind turbine;
(b) a resistor connected in parallel with the wind turbine and with said inductor;
(c) a first relay connected in series with said inductor and a second relay connected in series with said resistor;
(d) a control device connected with said first and second relays for controlling the operation of said relays to deliver power from the wind turbine to a selected inductor or resistor, thereby creating a desired constant load across the wind turbine that is not susceptible to voltage spikes and frequency variations for testing the wind turbine.

2. A load device as defined in claim 1, and further comprising a plurality of inductors and a plurality of resistors connected in parallel with the wind turbine and a plurality of relays, each relay being connected in series with one of said inductors and resistors and being connected with said control device.

3. A load device as defined in claim 1, and further comprising a computer connected with said control device for controlling the operation of said control device to select the inductive or resistive load to be applied across the wind turbine in accordance with a testing procedure.

4. A load device as defined in claim 2, and further comprising a manual bypass device connected with each of said relays for over-riding said control device and manually selecting an inductor or resistor for connection across the wind turbine.

5. A load bank for applying an active load on a power grid of a plurality of wind turbines, comprising
(a) a plurality of load devices, each including an inductor and a resistor connected in parallel, a first relay connected in series with said inductor, and a second relay connected in series with said resistor, and a control device connected with said first and second relays for controlling the operation of each relay to select an inductor or resistor as the load for each wind turbine of the power grid; and
(b) each of said load devices having an output connected with a load step terminal of each wind turbine of the power grid, whereby a desired constant load that is not susceptible to voltage spikes and frequency variations is generated across selected wind turbines of the power grid for testing the same.

6. A load bank as defined in claim 5, and further comprising a computer connected with said control devices of said load devices, respectively, for controlling the operation of said control devices to select one of an inductive or at least one of a resistive load from said load devices to be applied across selected load step terminals of the power grid in accordance with a testing procedure.
